(19) United States
(12) Patent Application Publication
(10) Pub. No.: US 2009/0233414 A1
(43) Pub. Date: Sep. 17, 2009

(54) Method for fabricating group III-nitride high electron mobility transistors (HEMTs)

(76) Inventors: Pankaj B. Shah, Rockville, MD (US); Michael Andrew Derenge, Columbia, MD (US)

Correspondence Address: U S ARMY RESEARCH LABORATORY;ATTN: RDRL-LOC-I, 2800 POWDER MILL RD, ADELPHI, MD, 20783-1197, US

(21) Appl. No.: 11/253,609

(22) Filed: Oct. 20, 2005

(51) Int. Cl. H01L 21/20

(52) U.S. Cl. 438/401; 438/478; 257/E21.09

(57) ABSTRACT

A method of manufacturing a transistor comprises providing a wafer; growing a group III-nitride semiconductor material on a first side of the wafer; creating alignment marks on a second side of the wafer, the second side of the wafer being positioned opposite to the first side of the wafer; etching the first side of the wafer to create free standing walls on the first side of the wafer; growing pendeo-epitaxy regrowth regions on the free standing walls; and forming mesa isolated regions in the pendeo-epitaxy regrowth regions. The method may further comprise positioning a patterned mask on the first side of the wafer; and aligning the patterned mask with the alignment marks located on the second side of the wafer.

### GOVERNMENT INTEREST

The embodiments of the invention described herein may be manufactured, used, and/or licensed by or for the United States Government.

### BACKGROUND

1. Field of the Invention

The embodiments of the invention generally relate to transistor devices and, more particularly, to high electron mobility transistors (HEMTs).

2. Description of the Related Art

Conventionally, HEMTs have been manufactured on GaN/AlGaN, InGaN/GaN/AlGaN and other similar multilayer structures. Unfortunately, these materials typically have many defects and this may adversely affect the device's performance. One result of this is that the conventional HEMTs typically do not provide the theoretically expected maximum frequency, voltage breakdown, current handling, and switching characteristics associated with these types of devices. The conventional solutions have generally been unable to place devices on pendeo-epitaxy regrowth regions of semiconductor wafers. This is, in part, because the regrowth regions are very small in size and also because it is generally difficult to align the active region of a semiconductor device with the regrowth regions to take advantage of the benefits that the improved material quality of pendeo-epitaxy regrowth offers. Conventional alignment techniques for aligning the active region of group III-nitride HEMTs generally involve placing alignment marks on the front surface of the wafer, which tends to lead to inaccurate alignment because the alignment marks will generally be altered by the regrowth process. Accordingly, there remains a need for a novel HEMT device and method of fabrication that overcomes the limitations of the conventional devices and techniques.

### SUMMARY

In view of the foregoing, an embodiment of the invention provides a method of manufacturing a transistor, wherein the method comprises providing a wafer; growing a group III-nitride semiconductor material on a first side of the wafer; creating alignment marks on a second side of the wafer, the second side of the wafer being positioned opposite to the first side of the wafer; etching the first side of the wafer to create free standing walls on the first side of the wafer; growing pendeo-epitaxy regrowth regions on the free standing walls; and forming mesa isolated regions in the pendeo-epitaxy regrowth regions. The method may further comprise positioning a patterned mask on the first side of the wafer; and aligning the patterned mask with the alignment marks located on the second side of the wafer. Additionally, the method may further comprise positioning a patterned mask on the pendeo-epitaxy regrowth regions; and aligning the patterned mask with the alignment marks located on the second side of the wafer. Preferably, the mesa isolated regions comprise active regions of a group III-nitride high election mobility transistor. The alignment marks may be created by positioning a patterned mask on the second side of the wafer; and etching the second side of the wafer. Alternatively, the alignment marks may be created by depositing a metal layer on the second side of the wafer; and using a liftoff technique to create an image of the alignment marks with the deposited metal layer. Preferably, the second side of the wafer comprises a substrate side of the wafer.

Another embodiment of the invention provides a method of forming a group 111-nitride high electron mobility transistor, wherein the method comprises providing a wafer comprising a first side opposite a second side, wherein the first side of the wafer comprises a group III-nitride semiconductor material; etching alignment marks in the second side of the wafer; creating free standing walls from the group III-nitride semiconductor material on the first side of the wafer; growing a pendeo-epitaxy region on the free standing walls; and forming at least one mesa isolated region in the pendeo-epitaxy region. The method may further comprise positioning a patterned mask on the first side of the wafer; and aligning the patterned mask with the alignment marks located on the second side of the wafer. Additionally, the method may further comprise positioning a patterned mask on the pendeo-epitaxy region; and aligning the patterned mask with the alignment marks located on the second side of the wafer. Preferably, the mesa isolated region comprises active regions of a group III-nitride high election mobility transistor. The alignment marks may be created by positioning a patterned mask on the second side of the wafer; and etching the second side of the wafer. Alternatively, the alignment marks may be created by depositing a metal layer on the second side of the wafer; and using a liftoff technique to create an image of the alignment marks with the deposited metal layer. Preferably, the second side of the wafer comprises a substrate side of the wafer.

Another aspect of the invention provides a method of fabricating a high electron mobility transistor, wherein the method comprises providing a semiconductor wafer comprising a top side and a bottom side, wherein the bottom side of the semiconductor wafer comprises a group III-nitride semiconductor material; positioning alignment marks in the top side of the semiconductor wafer; configuring free standing walls from the group III-nitride semiconductor material on the bottom side of the semiconductor wafer by etching the bottom side of the semiconductor wafer; performing a pendeo-epitaxy regrowth process to form pendeo-epitaxy regrowth regions from the free standing walls; and forming at least one mesa isolated region in the pendeo-epitaxy regrowth regions, wherein the at least one mesa isolated region comprises an active region of a group III-nitride high electron mobility transistor. The method may further comprise positioning a patterned mask on the bottom side of the semiconductor wafer; and aligning the patterned mask with the alignment marks located on the top side of the semiconductor wafer. Also, the method may further comprise positioning a patterned mask on the pendeo-epitaxy regrowth regions; and aligning the patterned mask with the alignment marks located on the top side of the semiconductor wafer. The alignment marks may be created by positioning a patterned mask on the top side of the semiconductor wafer; and etching the top side of the semiconductor wafer. Alternatively, the alignment marks may be created by depositing a metal layer on the top side of the semiconductor wafer; and using a liftoff technique to create an image of the alignment marks with the deposited metal layer. Preferably, the top side of the semiconductor wafer comprises a substrate side of the semiconductor wafer.

The embodiments of the invention provide an optimized pendeo-epitaxy regrowth process, which can be utilized to align the active region of HEMTs with the low defect density group III-nitride pendeo-epitaxy regrowth material. Moreover, the devices manufactured with the process provided by the embodiments of the invention may be used to produce a HEMT that performs better than conventional group III-nitride HEMT devices because their active region contains less defects than conventional group-III nitride HEMTs. The resulting devices can be used in radio frequency (RF) power amplifier and mixer circuits and may greatly enhance the capability of military and commercial communication systems, radar systems, and electronic warfare systems.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIGS. 1(A) through 6 illustrate schematic diagrams of successive processing steps according to the embodiments of the invention; and

FIG. 7 is a flow diagram illustrating a preferred method according to an embodiment of the invention.

### DETAILED DESCRIPTION OF PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

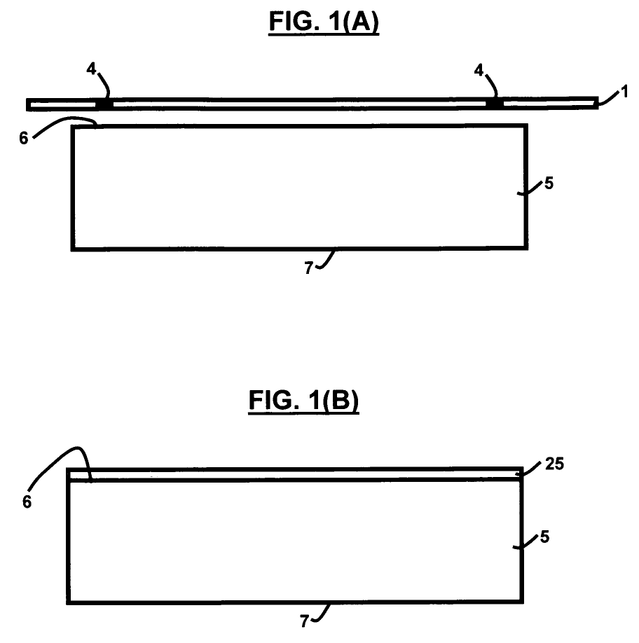

As mentioned, there remains a need for a novel HEMT device and method of fabrication that overcomes the limitations of the conventional devices and techniques. The embodiments of the invention achieve this by providing a technique for aligning devices to a pendeo-epitaxy regrowth material. Referring now to the drawings, and in particular to FIGS. 1(A) through 7, where similar reference characters denote corresponding features consistently throughout the figures, there are shown preferred embodiments of the invention. FIGS. 1(A) through 6 illustrate steps in the process for fabricating group III-nitride HEMTs with active regions aligned with pendeo-epitaxy regrowth group III-nitride regions. First, as indicated in FIG. 1(A), a semiconductor wafer 5 comprising a top (substrate) side 6 and a bottom (group III-nitride semiconductor material) side 7 is flipped over, and using mask 1, the mirror image of the alignment marks 4 are patterned on the top side 6 of the wafer 5. These marks 4 are referred to herein as the fundamental alignment mark set.

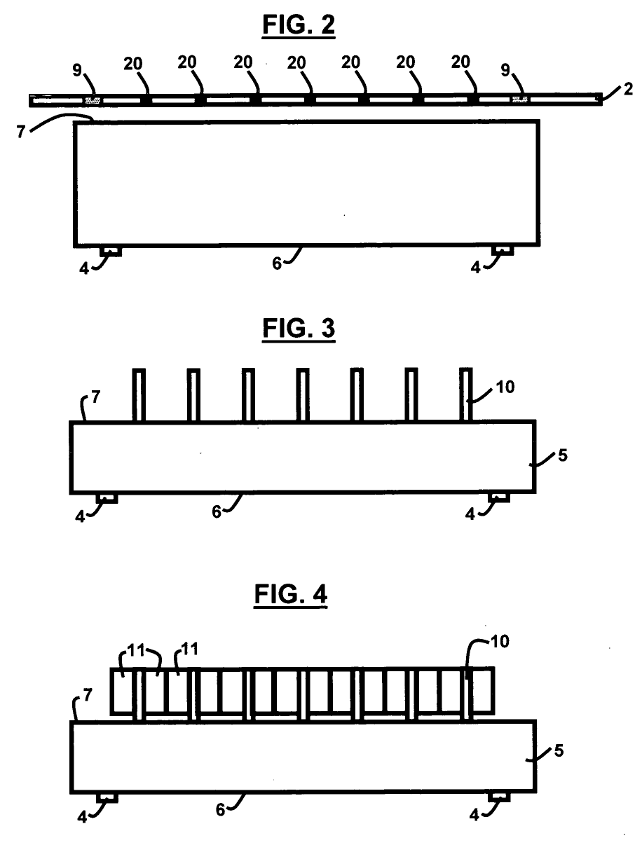

Alternatively, the marks 4 can be created in two other alternative ways without flipping the semiconductor wafer 5 over: (1) etching the marks 4 into the semiconductor wafer 5; or (2) using a technique to leave marks 4 on the top side 6 of the semiconductor wafer 5 using a metal layer 25 (as shown in FIG. 1(B)) and etched in the desired shape for the alignment marks 4 (shown in FIG. 2). For technique (2), the metal layer 25 could be (a) etched to form the shape, or (b) one could mask most of the top side 6 of the semiconductor wafer 5 with a resist material (not shown) and use a lithographic process that creates windows (not shown) to the underlying semiconductor wafer 5 in the resist layer. These windows are shaped like the desired alignment marks 4. Then, the metal layer 25 is deposited over the entire top side 6 of the semiconductor wafer 5. The metal layer 25 contacts the semiconductor wafer 5 where the windows are, but sits on top of the resist layer (not shown) in other areas. When the resist is dissolved, the metal remaining on the top side 6 of the semiconductor wafer 5 is in the form of the desired alignment marks 4.

The next step, as illustrated in FIG. 2, involves patterning the bottom (group III-nitride semiconductor material) side 7 of the wafer 5 with a second mask 2, having predefined patterns 20 and alignment marks 9, to define free standing walls 10 (shown in FIG. 3) for the subsequent pendeo-epitaxy regrowth step. This mask 2 should preferably be aligned with the aid of alignment marks 9 using the back side alignment with the appropriate alignment mark 4 in the fundamental alignment mark set.

As shown in FIG. 3, the free standing walls 10 are etched (using any well-known etching process) into the wafer 5. Thereafter, as indicated in FIG. 4, the pendeo-epitaxy material regrowth step occurs. During the regrowth process, group III-nitride material 11 such as GaN grows laterally on both sides of, and away from, the free standing wall 10 at a faster rate than the growth of the material vertically above the wall. When optimized, most of the growth occurs laterally until the laterally growing material from two adjacent walls 10 coalesce forming a flat surface. The regrowth process may occur as described in Zheleva, T. S., et al., “Pendeo-epitaxy—A New Approach for Lateral Growth of Gallium Nitride Structures,” MRS Internet J. Nitride Semicond. Res. 4S1, G3.38 (1999), the complete disclosure of which, in its entirety, is herein incorporated by reference. According to the embodiments of the invention, the group III-nitride pendeo-epitaxy regrowth material 11 has reduced defects compared to the free standing walls 10 from which they grow. The embodiments of the invention test this hypothesis by analyzing the group III-nitride pendeo-epitaxy regrowth material 11 using transmission electron microscopy (TEM) and verifying that there are fewer defects in the group III-nitride pendeo-epitaxy regrowth material 11 compared to the free standing walls 10. Accordingly, the embodiments of the invention provide an optimized technique of placing devices on the pendeo-epitaxy regrowth regions.

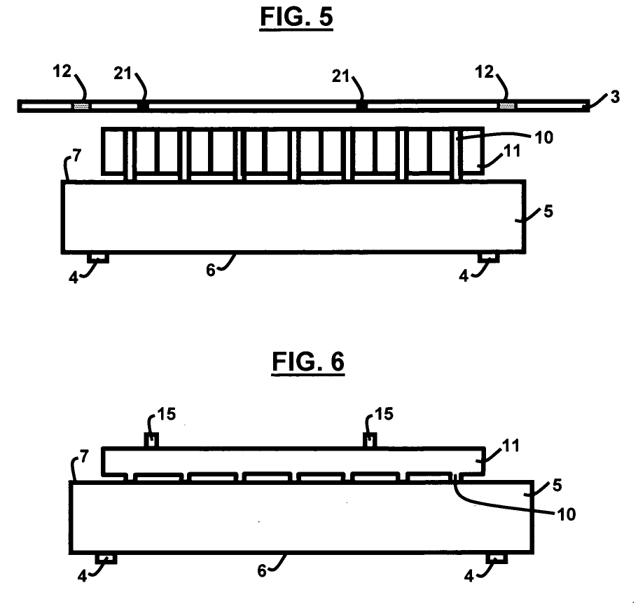

The next step of the process involves aligning a third mask 3, having predefined patterns 21 and alignment marks 12, with the HEMT process steps to the fundamental alignment marks 4 on the bottom side 7 of wafer 5 as depicted in FIG. 5. Thereafter, as indicated in FIG. 6, the process continues with well-known HEMT processing techniques. These process steps involve: (1) mesa isolation of the device using an etch process such as inductive coupled plasma reactive ion etching; (2) ohmic contact deposition; (3) ohmic contact annealing to improve electrical performance; (4) Schottky contact deposition; (5) passivation layer deposition; (6) via etching through the passivation layer, and (7) wire bond pad deposition. Additional alignment marks (not shown) for subsequent masks used in steps 1 through 7 described above could be placed either on the top side 6 or bottom side 7 of the wafer 5. FIG. 6 illustrates the mesa isolated region 15 that are the active regions of a HEMT. In this context, the active region is the region of critical interest when analyzing electrical performance. In the HEMT, the active region is the region between the source and drain contact (not shown) including that region under the gate (not shown). Here, the current from source to drain contact (not shown) is modulated in the semiconductor by the bias of the gate contact.

The embodiments of the invention provide a quick, simple, and efficient method for aligning the active region of high frequency HEMT devices with the high quality material produced by the pendeo-epitaxy regrowth step. This allows device manufacturers to make HEMTs with improved characteristics such as higher frequency operation, higher voltage handling capability, and faster switching performance. These advantages are achieved because the active region contains fewer defects due to being located on the better quality material. The group III-nitride pendeo-epitaxy regrowth material 11 has fewer defects (compared to the free standing walls 10) and has a high free carrier mobility leading to higher frequency operation. Also, the group III-nitride pendeo-epitaxy regrowth material 11, which has fewer defects offer free carriers paths to the HEMT channel (not shown) through a high reverse bias so that higher voltages can be blocked. Finally, with fewer defects, there are less trap states available to trap and detrap free carriers so that the switching mechanism is less affected by this.

The problem of aligning the active region of group III-nitride HEMTs with the better quality group III-nitride pendeo-epitaxy regrown material is solved according to the process provided by the embodiments of the invention. The embodiments of the invention may be used for aligning the active region of a group III-nitride device with the improved quality group III-nitride pendeo-epitaxy regrowth material 11.

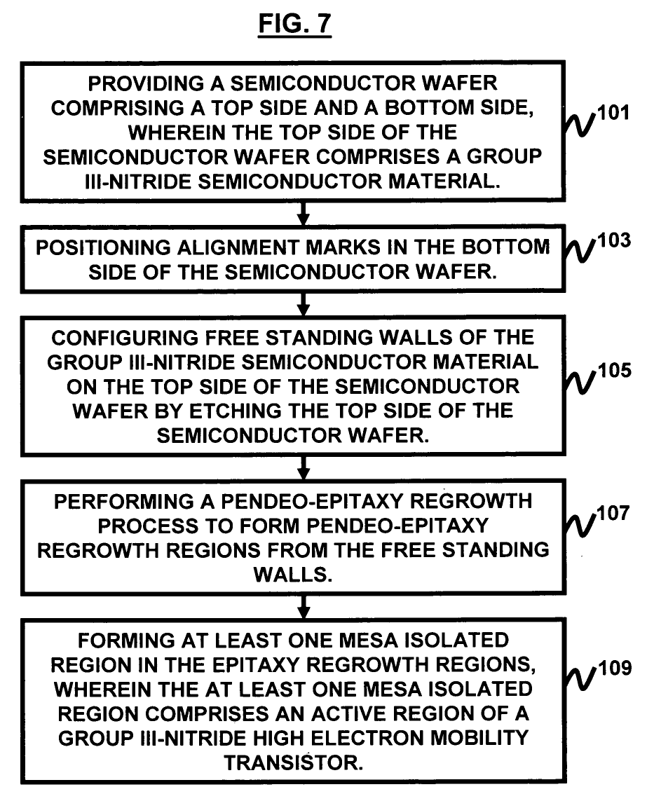

FIG. 7 (with reference to FIGS. 1(A) through 6) is a flow diagram illustrating a method of forming a group III-nitride high electron mobility transistor, wherein the method comprises providing (101) a semiconductor wafer 5 comprising a top side 6 and a bottom side 7, wherein the bottom side 7 of the semiconductor wafer 5 comprises a group III-nitride semiconductor material; positioning (103) alignment marks 4 in the top side 6 of the semiconductor wafer 5; configuring (105) free standing walls 10 of the group III-nitride semiconductor material on the bottom side 7 of the semiconductor wafer 5 by etching the bottom side 7 of the semiconductor wafer 5; performing (107) a pendeo-epitaxy regrowth process to form pendeo-epitaxy regrowth regions 11 from the free standing walls 10; and forming (109) at least one mesa isolated region 15 in the pendeo-epitaxy regrowth regions 11, wherein the at least one mesa isolated region 15 comprises an active region of a group III-nitride high electron mobility transistor (not shown).

The method may further comprise positioning a patterned mask 2 on the bottom side 7 of the wafer 5; and aligning the patterned mask 2 with the alignment marks 4 located on the top side 6 of the wafer 5. Also, the method may further comprise positioning a patterned mask 3 on the pendeo-epitaxy regrowth regions 11; and aligning the patterned mask 3 with the alignment marks 4 located on the top side 6 of the wafer. Preferably, the pendeo-epitaxy regrowth regions 11 grow laterally outward from the free standing walls 10. Furthermore, the alignment marks 4 may be created by positioning a patterned mask 1 on the top side 6 of the wafer 5; and etching the top side 6 of the wafer 5. Alternatively, the alignment marks 4 may be created by depositing a metal layer 25 on the top side 6 of the wafer 5; and using a liftoff technique to create an image of the alignment marks 4 with the deposited metal layer 25. Preferably, the top side 6 of the wafer 5 comprises a substrate side of the wafer 5.

The embodiments of the invention provide an optimized pendeo-epitaxy regrowth process, which can be utilized to align the active region of HEMTs with the low defect density group III-nitride pendeo-epitaxy regrowth material 11. Moreover, the devices manufactured with the process provided by the embodiments of the invention may be used to produce a HEMT that performs better than conventional group III-nitride HEMT devices because their active region contains less defects than conventional group-III nitride HEMTs. The resulting devices can be used in radio frequency (RF) power amplifier and mixer circuits and may greatly enhance the capability of military and commercial communication systems, radar systems, and electronic warfare systems.

The embodiments of the invention can be used to form integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of the specific embodiments will so fully reveal the general nature of the embodiments of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention has been described in terms of preferred embodiments, those skilled in the art will recognize that the embodiments of the invention can be practiced with modification within the spirit and scope of the appended claims.

1. A method of manufacturing a high electron mobility transistor, said method comprising:
providing a wafer;
growing a group III-nitride semiconductor material on a first side of said wafer;
creating alignment marks on a second side of said wafer using a first patterned mask; said second side of said wafer being positioned opposite to said first side of said wafer;
positioning a second patterned mask over said group III-nitride layer based upon alignment with said alignment marks;
etching said first side of said wafer in accordance with the pattern of said second patterned mask to create free standing walls on said first side of said wafer;
growing pendeo-epitaxy regrowth regions on said free standing walls; and
forming mesa regions within said pendeo-epitaxy regions;
determining the location of said mesa regions by utilizing a third patterned mask oriented and positioned over said first surface based upon said alignment marks; and
positioning the active regions of group III-nitride high electron mobility transistors over said mesa regions based upon the pattern in said third patterned mask.

2. The method of claim 1, wherein said second side comprises the substrate side of said wafer.

3. The method of claim 1, further comprising: wherein said second patterned mask and said third patterned mask each comprise predefined patterns and second alignment portions, said second alignment portions adapted to be juxtaposed relative to the location of said alignment marks on said side of said wafer.

4. The method of claim 1, wherein said second patterned mask and said third patterned mask each contain at least two second alignment portions.

5. The method of claim 1, wherein said alignment marks are created by:
positioning a patterned mask on said second side of said wafer; and
etching said second side of said wafer.

6. The method of claim 1, wherein said alignment marks are created by:
covering most of said second side with a resist material;
lithographically creating windows in said resist material corresponding to the position and shape of said alignment marks to create said first patterned mask;
depositing a metal layer on substantially the entire second side of said wafer; and
using a liftoff technique to create said alignment marks from the deposited metal layer remaining on said second side of said wafer.

7. The method of claim 6, wherein said second side of said wafer comprises a substrate side of said wafer and wherein said first patterned mask is formed from resist material which is dissolved leaving the metal remaining only on the portions occupied by the windows.

8. A method of forming a group III-nitride high electron mobility transistor, said method comprising:
providing a wafer comprising a first side opposite a second side, wherein said first side of said wafer comprises a group III-nitride semiconductor material;
etching alignment marks in said second side of said wafer;
creating free standing walls from said group III-nitride semiconductor material on said first side of said wafer;
growing a pendeo-epitaxy region on said free standing walls; and
forming at least one mesa isolated region in said pendeo-epitaxy region.

9. The method of claim 8, further comprising:
positioning a patterned mask on said first side of said wafer; and
aligning said patterned mask with said alignment marks located on said second side of said wafer.

10. The method of claim 8, further comprising:
positioning a patterned mask on said pendeo-epitaxy region; and
aligning said patterned mask with said alignment marks located on said second side of said wafer.

11. The method of claim 8, wherein said mesa isolated region comprises active regions of a group III-nitride high electron mobility transistor.

12. The method of claim 8, wherein said alignment marks are created by:
positioning a patterned mask on said second side of said wafer; and
etching said second side of said wafer.

13. The method of claim 8, wherein said alignment marks are created by:
depositing a metal layer on said second side of said wafer; and
using a liftoff technique to create an image of said alignment marks with the deposited metal layer.

14. The method of claim 8, wherein said second side of said wafer comprises a substrate side of said wafer.

15. A method of fabricating a high electron mobility transistor, said method comprising:
providing a semiconductor wafer comprising a top side and a bottom side, wherein said bottom side of said semiconductor wafer comprises a group III-nitride semiconductor material;
positioning alignment marks in said top side of said semiconductor wafer;
configuring free standing walls from said group III-nitride semiconductor material on said bottom side of said semiconductor wafer by etching said bottom side of said semiconductor wafer;
performing a pendeo-epitaxy regrowth process to form pendeo-epitaxy regrowth regions from said free standing walls; and
forming at least one mesa isolated region in said epitaxy regrowth regions,
wherein said at least one mesa isolated region comprises an active region of a group III-nitride high electron mobility transistor.

16. The method of claim 15, further comprising:
positioning a patterned mask on said bottom side of said semiconductor wafer; and
aligning said patterned mask with said alignment marks located on said top side of said semiconductor wafer.

17. The method of claim 15, further comprising:
positioning a patterned mask on said pendeo-epitaxy regrowth regions; and
aligning said patterned mask with said alignment marks located on said top side of said semiconductor wafer.

18. The method of claim 15, wherein said alignment marks are created by:
positioning a patterned mask on said top side of said semiconductor wafer; and
etching said top side of said semiconductor wafer.

19. The method of claim 15, wherein said alignment marks are created by:
depositing a metal layer on said top side of said semiconductor wafer; and
using a liftoff technique to create an image of said alignment marks with the deposited metal layer.

20. The method of claim 15, wherein said top side of said semiconductor wafer comprises a substrate side of said semiconductor wafer.
